(19) United States
(12) Patent Application Publication
(10) Pub. No.: US 2026/0214814 A1
(43) Pub. Date: Jul. 23, 2026

(54) POWER SYSTEM AND POWER MODULE

(71) Applicant: DELTA ELECTRONICS, INC., Taoyuan City (TW)

(72) Inventor: Chun-Han LIN, Taoyuan City (TW)

(21) Appl. No.: 19/177,663

(22) Filed: Apr. 14, 2025

(30) Foreign Application Priority Data
Jan. 22, 2025 (CN) 202510100005.X

(51) Int. Cl. H05K 5/00; H05K 5/02

(52) U.S. Cl. CPC H05K 5/0069; H05K 5/0221; H05K 5/0247; H05K 5/0286

(57) ABSTRACT

A power system includes a cabinet, an insulating extension arm, a conductive bar, a fixing member, and a power cord. The cabinet has an interior space and a bracket located in the interior space. The insulating extension arm is located in the interior space and fixed to the bracket. The conductive bar is located in the interior space. The fixing member passes through the conductive bar and is connected to the insulating extension arm, and allows the conductive bar to move toward and away from the insulating extension arm. One end of the power cord is electrically coupled to the conductive bar. A power module configured to be inserted into the interior space includes a housing and a circuit board. The circuit board is fixed to the housing and includes an electrical connector having a connection port configured to plug into the conductive bar.

This application claims priority to China Application Serial Number 202510100005.X, filed January 22, 2025, which is herein incorporated by reference.

### BACKGROUND

### Technical Field

The present disclosure relates to a power system and a power module.

### Description of Related Art

Currently, for the power backplane structure located behind existing power modules, floating connectors commonly available on the market are mostly used to overcome tolerance issues during assembly. However, the aforementioned floating connectors not only have specific specifications, but also have specification limitations such as small floating range, high unit price, low rated voltage, and excessively small rated current, which often affect product design. With the trend of increasing input/output voltage and current of power modules, such floating connectors will not be sufficient.

Accordingly, how to provide a power system and a power module to solve the aforementioned problems becomes an important issue to be solved by those in the industry.

### SUMMARY

A purpose of the disclosure is to provide a power system and a power module that can efficiently solve the aforementioned problems.

In order to achieve the above purpose, according to an embodiment of the disclosure, a power system includes a cabinet, an insulating extension arm, a conductive bar, a fixing member, and a power cord. The cabinet has an interior space and a bracket located in the interior space. The insulating extension arm is located in the interior space and fixed to the bracket. The conductive bar is located in the interior space. The fixing member passes through the conductive bar and is connected to the insulating extension arm, and allows the conductive bar to move toward and away from the insulating extension arm. The power cord has an end electrically coupled to the conductive bar.

In one or more embodiments of the disclosure, the insulating extension arm has a surface facing the conductive bar. The fixing member includes a through portion and a head portion. The through portion passes through the conductive bar and abuts against the surface of the insulating extension arm. The head portion is connected to the through portion and located on a side of the conductive bar away from the insulating extension arm. The conductive bar is configured to be movable along the through portion between the surface of the insulating extension arm and the head portion.

In one or more embodiments of the disclosure, the power system further includes another insulating extension arm, another conductive bar, another fixing member, and an insulating member. The another insulating extension arm is located in the interior space and fixed to the bracket. The another conductive bar is located in the interior space. The another fixing member passes through the another conductive bar and is fixed to the another insulating extension arm, and allows the another conductive bar to move toward and away from the another insulating extension arm. The insulating member is abutted between the insulating extension arm and the another insulating extension arm.

In one or more embodiments of the disclosure, the fixing member passes through the insulating extension arm and is fastened to the insulating member. The another fixing member passes through the another insulating extension arm and is fastened to the insulating member.

In one or more embodiments of the disclosure, the insulating extension arm has a lateral extension portion. The lateral extension portion has an edge away from the bracket. The edge has a guiding surface.

In one or more embodiments of the disclosure, the conductive bar includes a plugging portion. The plugging portion has an edge away from the bracket. The edge has a guiding surface.

In one or more embodiments of the disclosure, the power system further includes another fixing member. The another fixing member passes through the bracket and is fixed to the insulating extension arm, and allows the bracket to move toward and away from the insulating extension arm.

In one or more embodiments of the disclosure, the power system further includes a guiding seat. The guiding seat is connected to the insulating extension arm and has a guiding hole.

In one or more embodiments of the disclosure, the power system further includes a fixing assembly. The fixing assembly includes a spacer post and a fastening member. The spacer post passes through the insulating extension arm. The fastening member includes a through portion and a head portion connected to each other. The through portion passes through the spacer post and passes into the bracket. The spacer post is abutted between the bracket and the head portion. The insulating extension arm is movably retained between the bracket and the head portion.

In one or more embodiments of the disclosure, the power system further includes a fixing assembly. The fixing assembly includes a spacer post, a fastening member, and a nut. The spacer post passes through the insulating extension arm. The fastening member includes a through portion and a fastening portion connected to each other. The through portion passes through the bracket. The nut is detachably fastened to the fastening member. The spacer post is abutted between the bracket and the nut. The insulating extension arm is movably retained between the bracket and the nut.

In order to achieve the above purpose, according to an embodiment of the disclosure, a power module is configured to be inserted into the interior space of the power system. The power module includes a housing and a circuit board. The circuit board is fixed in the housing and includes an electrical connector. The electrical connector has a connection port. The connection port is configured for the conductive bar to plug into.

In one or more embodiments of the disclosure, the housing includes a sidewall. The sidewall has a notch. The notch is configured for the insulating extension arm of the power system to pass through. The sidewall has a guiding surface configured to guide the insulating extension arm at the notch.

In one or more embodiments of the disclosure, an entrance of the connection port has a guiding surface configured to guide the conductive bar.

In one or more embodiments of the disclosure, the power module further includes a guiding pin connected to the housing. The power system further includes a guiding seat. The guiding seat has a guiding hole. The guiding pin is configured to slidably insert into the guiding hole.

In order to achieve the above purpose, a power system includes a cabinet, an insulating extension arm, a conductive bar, a fixing member, and a power cord. The cabinet has an interior space and a bracket located in the interior space. The interior space is configured for a power module to insert into. The insulating extension arm is located in the interior space and fixed to the bracket. The conductive bar is located in the interior space and configured to plug into a connection port of the power module. The fixing member passes through the conductive bar and is connected to the insulating extension arm, and allows the conductive bar to move toward and away from the insulating extension arm. The power cord has an end electrically coupled to the conductive bar.

In summary, in the power system of the present disclosure, the fixing member that fixes the conductive bar to the insulating extension arm allows the conductive bar to move toward and away from the insulating extension arm. Therefore, during the period when the power module of the disclosure is inserted into the cabinet of the power system and the conductive bar is inserted into the electrical connector of the power module, the floating design of the conductive bar relative to the insulating extension arm can effectively eliminate assembly tolerances between the electrical connector and the conductive bar. Since the conductive bar has the advantages of low cost, high reworkability, high current resistance, and high rated voltage, it can replace the conventional floating connector with specification limitations. By providing a guiding surface at the entrance of the connection port of the electrical connector and/or at the edge of the conductive bar inserted into the electrical connector, and with the floating mechanism of the conductive bar, the assembly tolerance can be maximized. By designing the housing of the power module with a notch for the insulating extension arm to pass through, and providing a guiding surface at the edge of the insulating extension arm and/or at the notch, the influence of the manufacturing tolerance of the power system on the assembly tolerance between the electrical connector and the conductive bar can be effectively eliminated. By providing a combination of a guiding pin and a guiding seat between the power module and the power system, the purpose of eliminating the aforementioned manufacturing tolerance on the assembly tolerance can also be achieved.

The above is only used to describe the problems to be solved by the present disclosure, technical solutions to solve the problems and their effects, and so on. Specific details of the present disclosure will be described in the following embodiments with reference to relevant drawings.

### BRIEF DESCRIPTION OF THE DRAWINGS

In order to make the above and other purposes, features, advantages, and embodiments of the present disclosure easier to understand, the accompanying drawings are provided and described as follows.

FIG. 1 is a schematic diagram illustrating a power system according to an embodiment of the present disclosure;

FIG. 2 is a schematic diagram illustrating some components of the power system and some components of a power module according to an embodiment of the present disclosure;

FIG. 3 is a partial enlarged view of the components in FIG. 2 at a different viewing angle;

FIG. 4 is another partial enlarged view of the components in FIG. 2;

FIG. 5 is a partial side view of the components in FIG. 3;

FIG. 6 is a perspective view of a conductive bar;

FIG. 7 is a partial enlarged view of FIG. 3;

FIG. 8 is a partial enlarged view of the components in FIG. 3 at a different viewing angle;

FIG. 9 is a schematic diagram illustrating some components of a power system and some components of a power module according to another embodiment of the present disclosure;

FIG. 10 is a partial schematic diagram illustrating a bracket, an insulating extension arm, and a fixing assembly according to another embodiment of the present disclosure;

FIG. 11A is a schematic diagram illustrating the fixing assembly in FIG. 10; and

FIG. 11B is an exploded view of the fixing assembly in FIG. 11A.

### DETAILED DESCRIPTION

A plurality of embodiments of the present disclosure will be described below with reference to the accompanying drawings. For the sake of clarity, many practical details will be described together in the following description. However, it should be understood that these practical details should not be used to limit the present disclosure. That is to say, in some embodiments of the present disclosure, these practical details are not necessary. In addition, for the sake of simplifying the accompanying drawings, some commonly used structures and components are illustrated in the accompanying drawings in a simple schematic manner.

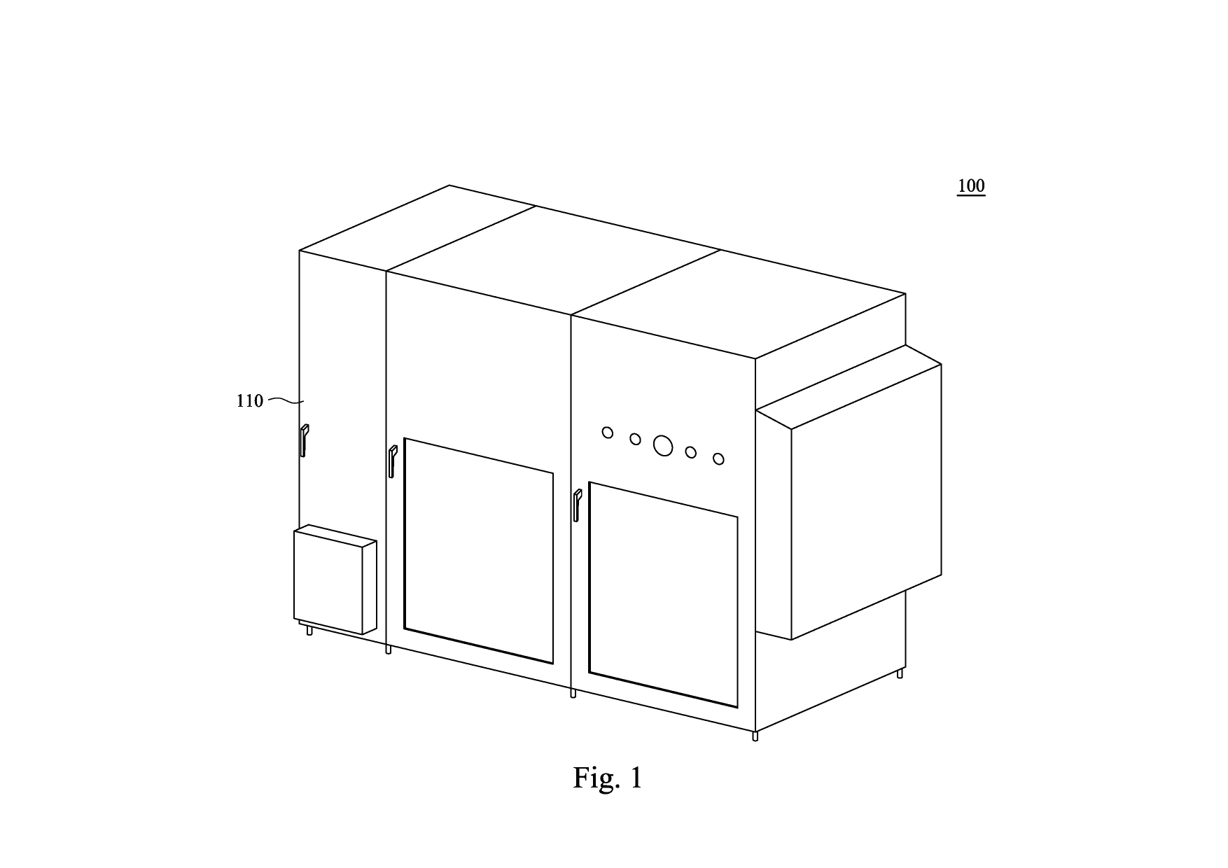

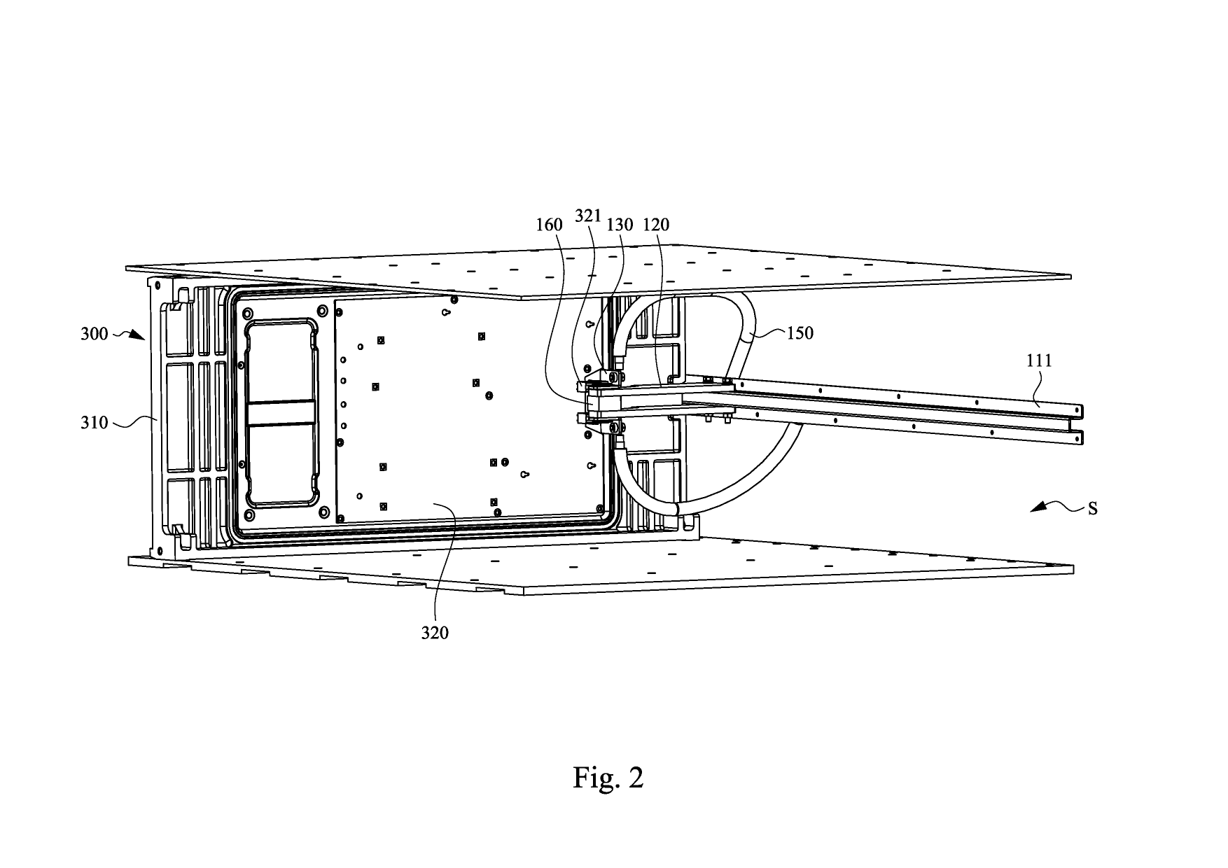

Reference is made to FIG. 1 and FIG. 2. FIG. 1 is a schematic diagram illustrating a power system 100 according to an embodiment of the present disclosure. FIG. 2 is a schematic diagram illustrating some components of the power system 100 and some components of a power module 300 according to an embodiment of the present disclosure. As shown in FIG. 1 and FIG. 2, in this embodiment, the power system 100 includes a cabinet 110, an insulating extension arm 120, a conductive bar 130, and a power cord 150. The cabinet 110 has an interior space S and a bracket 111 located in the interior space S. The insulating extension arm 120 is located in the interior space S and fixed to the bracket 111. The conductive bar 130 is located in the interior space S and disposed on the insulating extension arm 120. One end of the power cord 150 is electrically coupled to the conductive bar 130. The power module 300 is configured to be inserted into the interior space S of the power system 100. The power module 300 includes a housing 310 and a circuit board 320. The circuit board 320 is fixed in the housing 310 and includes an electrical connector 321. The electrical connector 321 is configured to plug into the conductive bar 130 of the power system 100.

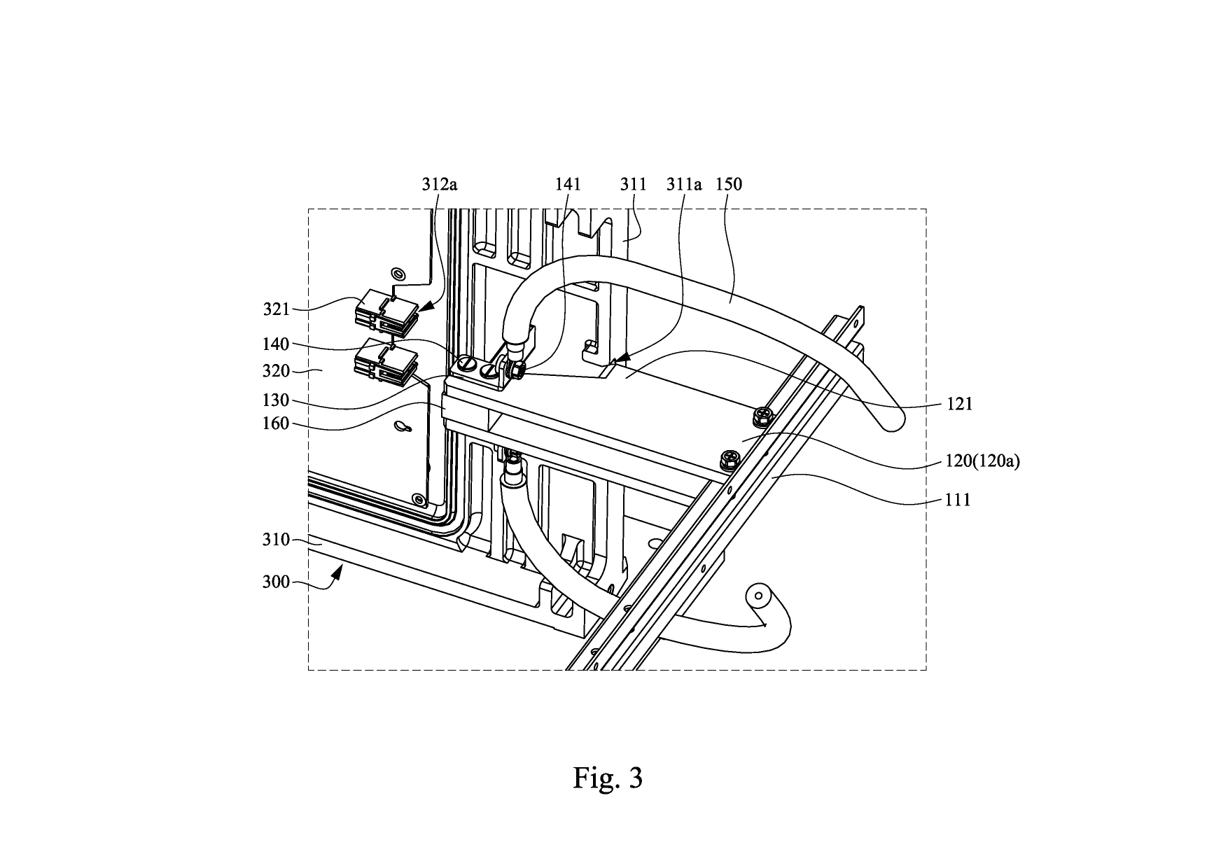

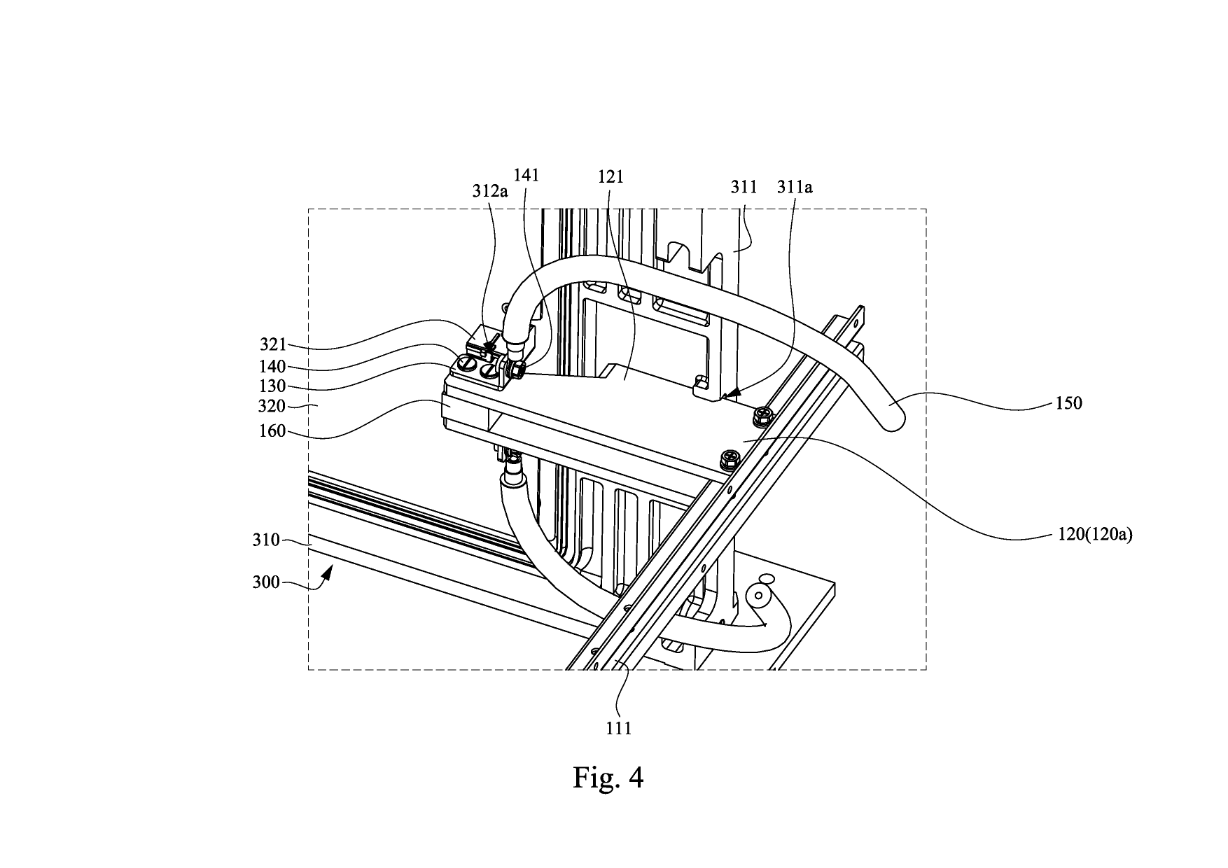

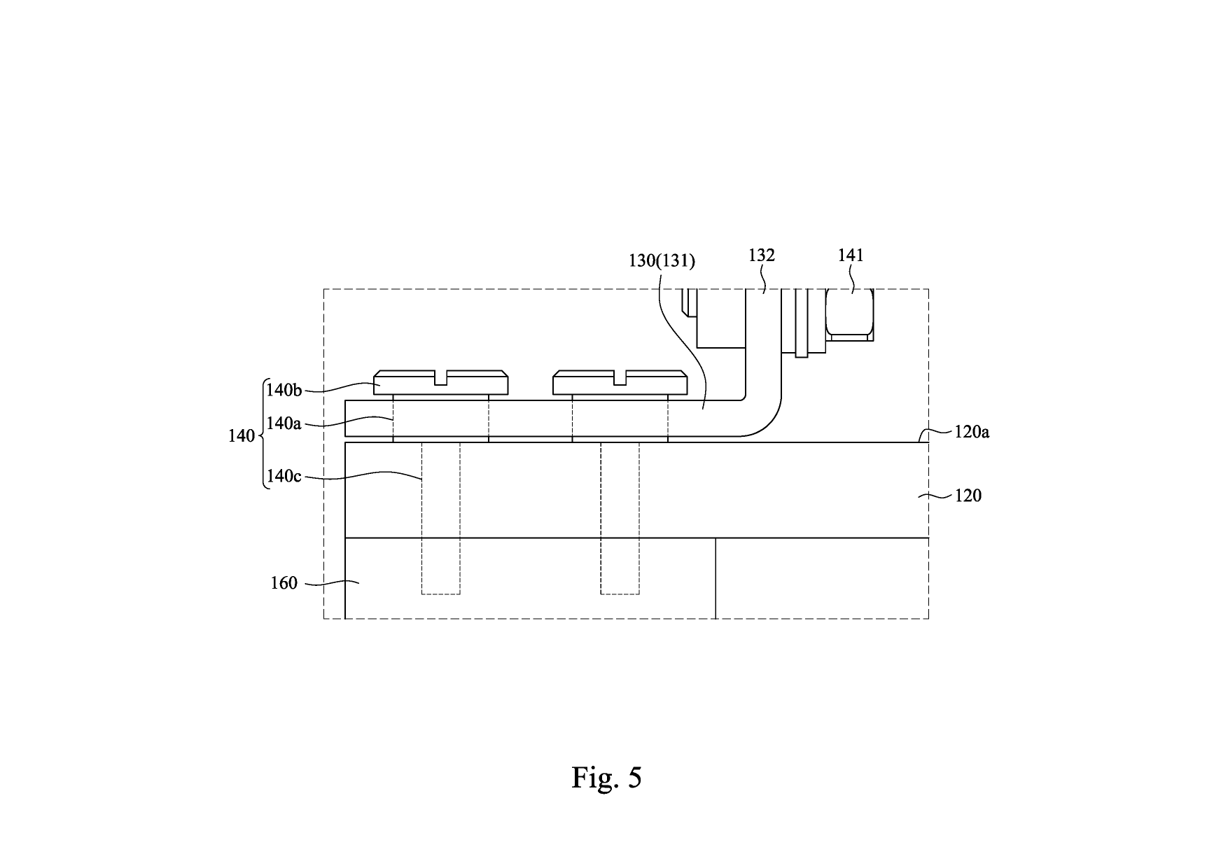

Reference is made to FIG. 3, FIG. 4, and FIG. 5. FIG. 3 is a partial enlarged view of the components in FIG. 2 at a different viewing angle. FIG. 4 is another partial enlarged view of the components in FIG. 2. FIG. 5 is a partial side view of the components in FIG. 3. As shown in FIGS. 3 to 5, in this embodiment, the power system 100 further includes a fixing member 140. The fixing member 140 passes through the conductive bar 130 and is connected to the insulating extension arm 120, and allows the conductive bar 130 to move toward and away from the insulating extension arm 120. In this way, in the period that the power module 300 inserts into the interior space S of the cabinet 110 to make the conductive bar 130 plug into the electrical connector 321 of the power module 300, the floating design of the conductive bar 130 relative to the insulating extension arm 120 can effectively eliminate the assembly tolerance between the electrical connector 321 and the conductive bar 130.

Specifically, as shown in FIG. 5, in this embodiment, the insulating extension arm 120 has a surface 120a facing the conductive bar 130. The fixing member 140 includes a through portion 140a (partially indicated by a dashed line) and a head portion 140b. The through portion 140a passes through the conductive bar 130 and abuts against the surface 120a of the insulating extension arm 120. The head portion 140b is connected to the through portion 140a and is located on a side of the conductive bar 130 away from the insulating extension arm 120. Since a thickness of the conductive bar 130 is less than a thickness of the through portion 140a, the conductive bar 130 can move along the through portion 140a between the surface 120a of the insulating extension arm 120 and the head portion 140b.

As shown in FIG. 3, in this embodiment, the power system 100 includes two sets of combinations of the insulating extension arm 120, the conductive bar 130, and the fixing member 140, and further includes an insulating member 160. The two sets of combinations of the insulating extension arm 120, the conductive bar 130, and the fixing member 140 are respectively disposed on the upper and lower sides of the insulating member 160 in a symmetrical manner. Specifically, the insulating member 160 is abutted between the two insulating extension arms 120. Due to the viewing angle, only a small part of the conductive bar 130 located on the lower side of the insulating member 160 is visible, and the fixing member 140 located on the lower side of the insulating member 160 is blocked and not shown.

As shown in FIG. 5, in this embodiment, the fixing member 140 further includes a fastening portion 140c (indicated by a dashed line). The fastening portion 140c is connected to one end of the through portion 140a away from the head portion 140b, and passes through the insulating extension arm 120 to be fastened to the insulating member 160. As can be seen from FIG. 5, an outer diameter of the through portion 140a is larger than an outer diameter of the fastening portion 140c and smaller than an outer diameter of the head portion 140b. Thus, it can be seen that the outer shape of the fixing member 140 is stepped. Therefore, the fixing member 140 can be referred to as a stepped screw (or referred to as a floating screw).

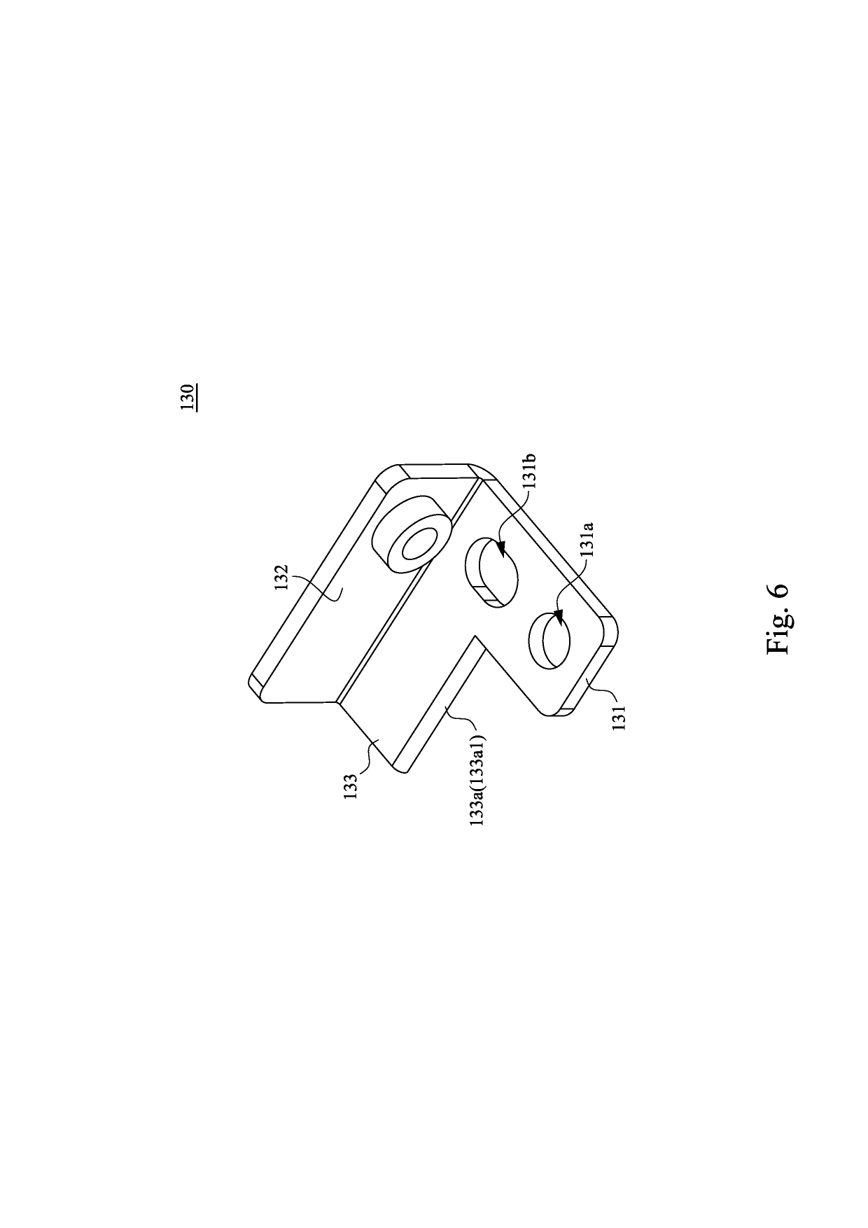

Reference is made to FIG. 6, which is a perspective view of the conductive bar 130. As shown in FIG. 6 with reference to FIG. 3, in this embodiment, the conductive bar 130 specifically includes a first fixing portion 131, a second fixing portion 132, and a plugging portion 133. The plugging portion 133 is laterally and parallelly connected to the first fixing portion 131. The second fixing portion 132 is bent and connected to the same side of the first fixing portion 131 and the plugging portion 133. The first fixing portion 131 includes two through holes 131a, 131b. The two fixing members 140 respectively pass through the two through holes 131a, 131b and are connected to the insulating extension arm 120. The through hole 131a is a circular hole, and the through hole 131b is a slotted hole extending away from the through hole 131a. The through hole 131b in the form of a slotted hole can eliminate the assembly tolerance when the two fixing members 140 fasten the conductive bar 130 to the insulating extension arm 120. The power system 100 further includes another type of fixing member 141. The fixing member 141 fastens one end of the power cord 150 to the second fixing portion 132. The plugging portion 133 is configured to insert into the connection port 321a of the electrical connector 321 of the power module 300.

In some embodiments, the material of the conductive bar 130 includes copper, so it may be referred to as a copper bar, but the present disclosure is not limited thereto. It should be noted that, since the structure of the conductive bar 130 is simple (it can be formed from a metal sheet, for example, through a stamping process), it has advantages such as low cost, reworkability, high current carrying capacity, and high rated voltage (by increasing the size), so that it can replace the conventional floating connector with specification limitations.

In detail, the voltage difference of the contacts inside the power module 300 of this embodiment is also not affected by the specifications of the conventional floating connector, and only the safety distance between the two electrical connectors 321 needs to be kept. The safety distance between the power module 300 and the power system 100 can also be achieved only by adjusting the extension length of the insulating extension arm 120 relative to the bracket 111. The rated input and output currents are only determined by the size of the conductive bar 130, so there is no need to apply for additional safety certification.

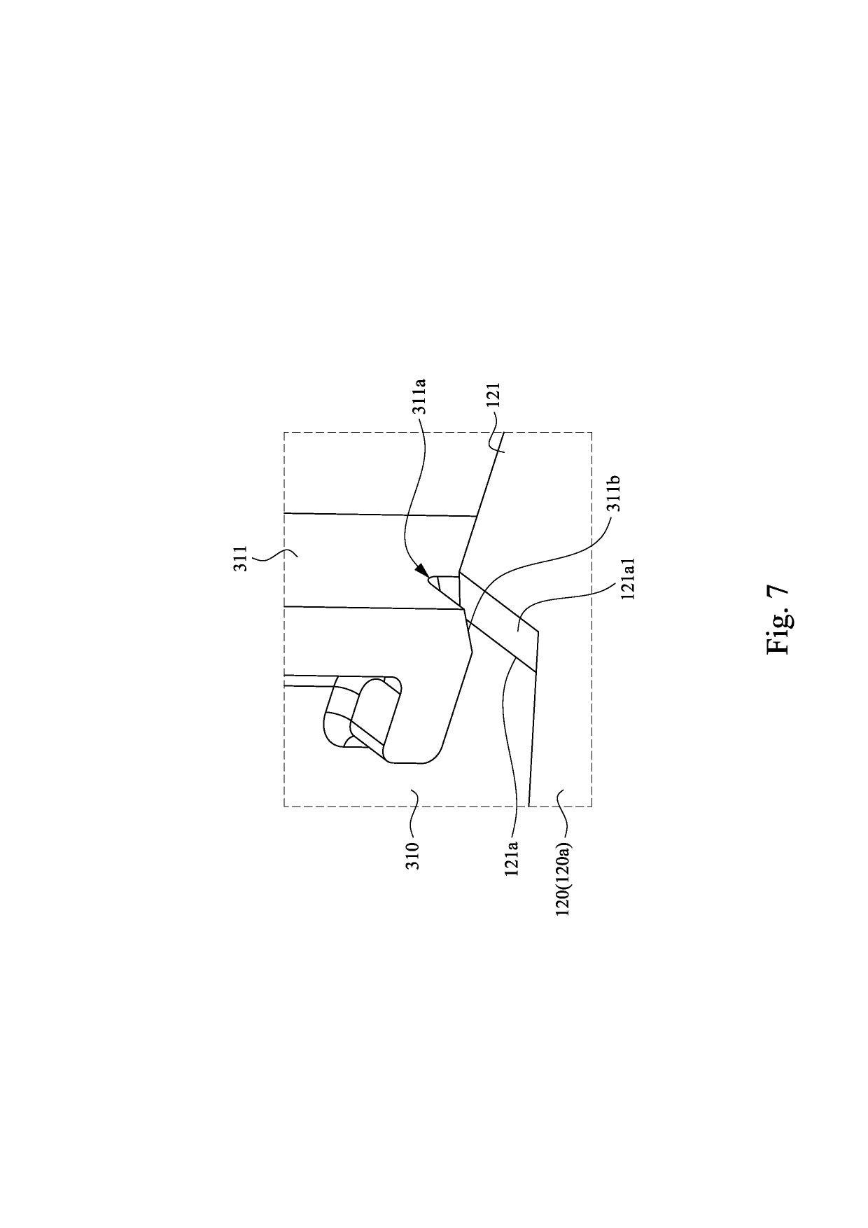

Reference is made to FIG. 7, which is a partial enlarged view of FIG. 3. As shown in FIG. 7, in this embodiment, the insulating extension arm 120 has a lateral extension portion 121. The lateral extension portion 121 has an edge 121a away from the bracket 111. The edge 121a has a guiding surface 121a1. In addition, the housing 310 of the power module 300 includes a sidewall 311. The sidewall 311 has a notch 311a. The notch 311a is configured for the insulating extension arm 120 of the power system 100 to pass through. The sidewall 311 has a guiding surface 311b at the notch 311a, which is configured to guide the insulating extension arm 120. In this way, the influence of the manufacturing tolerance of the power system 100 on the assembly tolerance between the electrical connector 321 and the conductive bar 130 can be effectively eliminated. In detail, when the power module 300 inserts into the cabinet 110 of the power system 100 to make the conductive bar 130 plug into the electrical connector 321 of the power module 300 (that is, during the period from FIG. 3 to FIG. 4), the guiding surface 121a1 of the lateral extension portion 121 and the guiding surface 311b of the sidewall 311 can perform the first stage guidance (or preliminary guidance) between the power system 100 and the power module 300, which helps the conductive bar 130 to smoothly plug into the electrical connector 321.

In practical applications, it is possible to selectively have a design with only one of the guiding surface 121a1 of the lateral extension portion 121 and the guiding surface 311b of the sidewall 311, which can still achieve the aforementioned guiding effect.

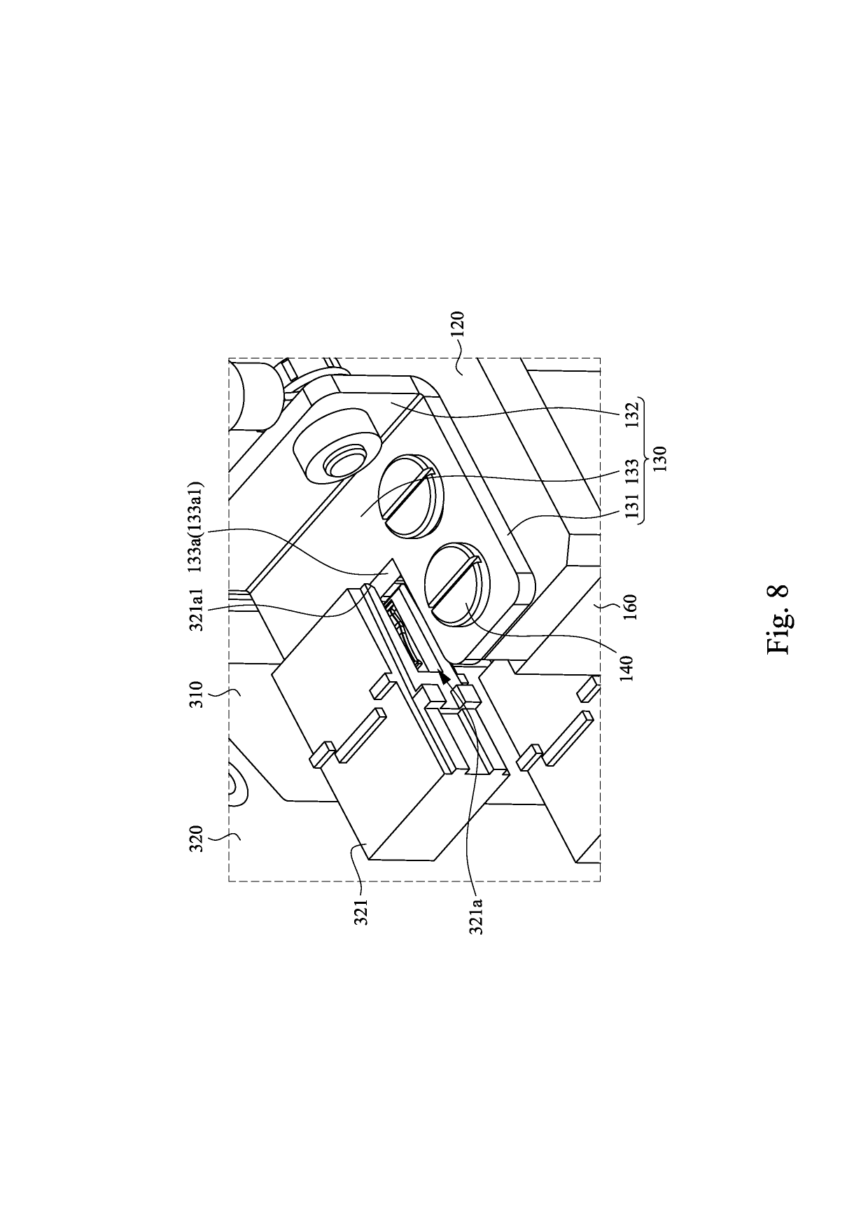

Reference is made to FIG. 8, which is a partial enlarged view of the components in FIG. 3 at a different viewing angle. As shown in FIG. 8, in this embodiment, the plugging portion 133 of the conductive bar 130 has an edge 133a away from the bracket 111. The edge 133a has a guiding surface 133a1. In addition, an entrance of the connection port 321a of the electrical connector 321 has a guiding surface 321a1 configured to guide the conductive bar 130. With the aforementioned floating mechanism of the conductive bar 130, the assembly tolerance can be maximized. In detail, when the power module 300 inserts into the cabinet 110 of the power system 100 to make the conductive bar 130 plug into the electrical connector 321 of the power module 300 (that is, during the period from FIG. 3 to FIG. 4), the guiding surface 321a1 of the electrical connector 321 and the guiding surface 133a1 of the plugging portion 133 can perform the second stage guidance (or fine guidance) between the power system 100 and the power module 300, which can further help the conductive bar 130 to smoothly plug into the electrical connector 321.

In FIG. 8, the guiding surface 133a1 of the plugging portion 133 is a circular arc surface, but the present disclosure is not limited thereto. In practical applications, the guiding surface 133a1 of the plugging portion 133 may also be a chamfered slope.

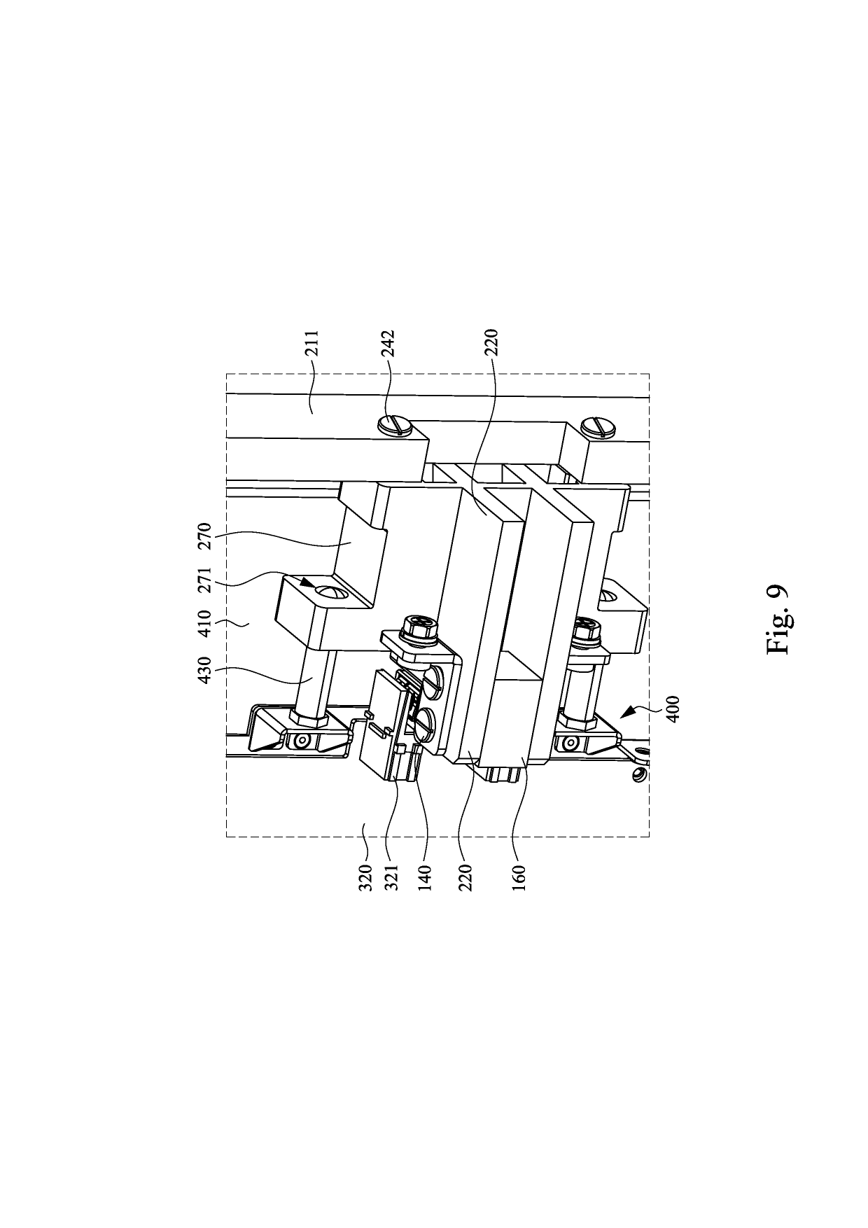

Reference is made to FIG. 9, which is a schematic diagram illustrating some components of the power system 100 and some components of the power module 400 according to another embodiment of the present disclosure. As shown in FIG. 9, compared to the embodiment shown in FIG. 3, the power system 100 of this embodiment further includes a guiding seat 270. The guiding seat 270 may also be referred to as a system-side floating module of the power system 100. The guiding seat 270 is connected to the insulating extension arm 220 and has a guiding hole 271. In addition to including the housing 410 and the circuit board 320 disposed on the housing 410, the power module 400 further includes a guiding pin 430. The guiding pin 430 is connected to the housing 410. The guiding seat 270 has a guiding hole 271. The guiding pin 430 is configured to slidably insert into the guiding hole 271. With the combination of the guiding pin 430 and the guiding seat 270, the purpose of eliminating the influence of the aforementioned manufacturing tolerance on the assembly tolerance can also be achieved.

In this embodiment, the guiding seat 270 and the insulating extension arm 220 are manufactured in one piece (that is, the two constitute a unitary structure), but the present disclosure is not limited thereto. In practical applications, the guiding seat 270 and the insulating extension arm 220 may also be two separate components, and connected by, for example, bonding, screw locking, or other methods.

As shown in FIG. 9, in this embodiment, the bracket 211 is fixed to the guiding seat 270 via a fixing member 242. The fixing member 242 passes through the bracket 211 and is fixed to the guiding seat 270, and allows the bracket 211 to move toward and away from the guiding seat 270. This means that the bracket 211 can also move relative to the insulating extension arm 220. The fixing member 242 may have a structure similar to that of the fixing member 140 shown in FIG. 5 (that is, a stepped screw). In this way, there is also a floating design between the bracket 211 and the guiding seat 270, which can further increase the assembly tolerance.

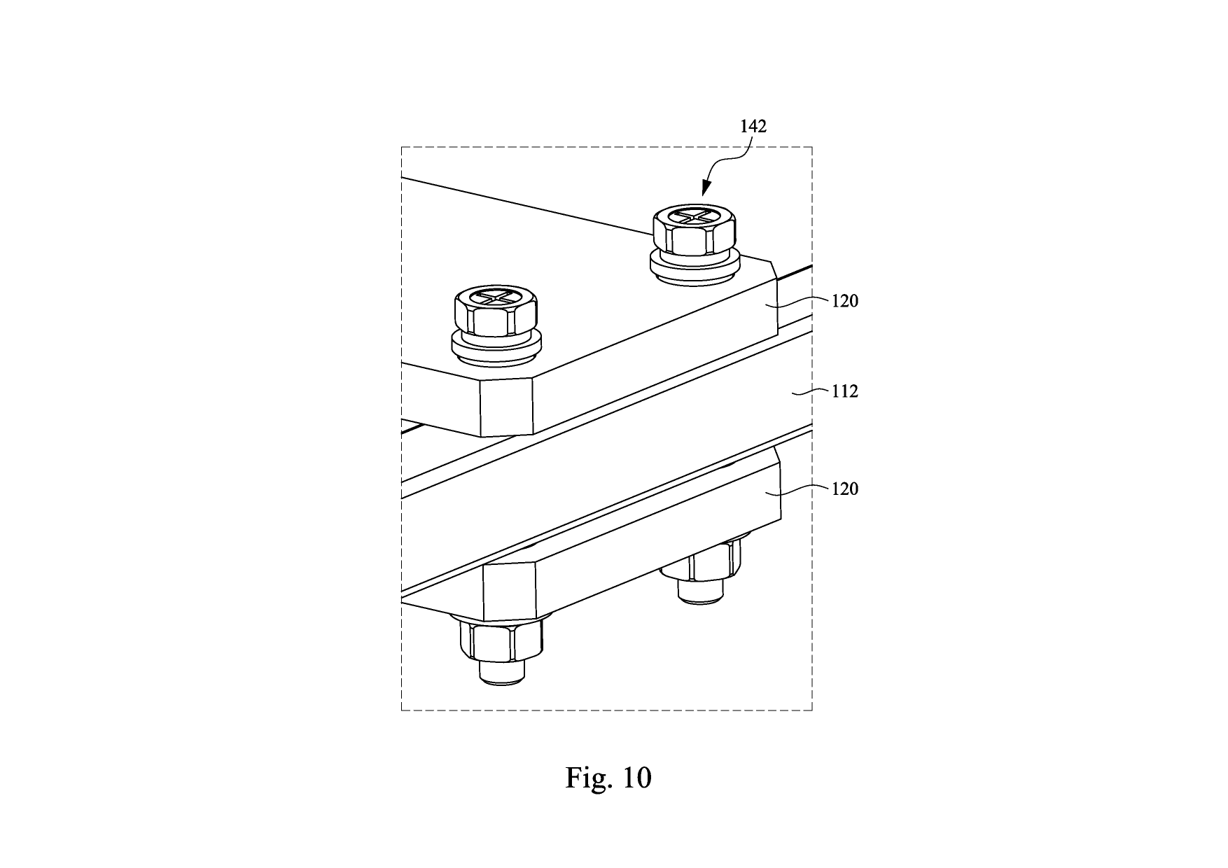

Reference is made to FIG. 10, which is a partial schematic diagram illustrating a bracket 112, the insulating extension arm 120, and the fixing assembly 142 according to another embodiment of the present disclosure. The insulating extension arm 120 shown in FIG. 10 is the same as that of the embodiment shown in FIG. 3, so the aforementioned related description can be referred and will not be repeated here. The bracket 112 is another example of the bracket 111 in FIG. 3. It should be noted that the two insulating extension arms 120 in this embodiment are movably fixed to opposite sides of the bracket 112 via the fixing assembly 142.

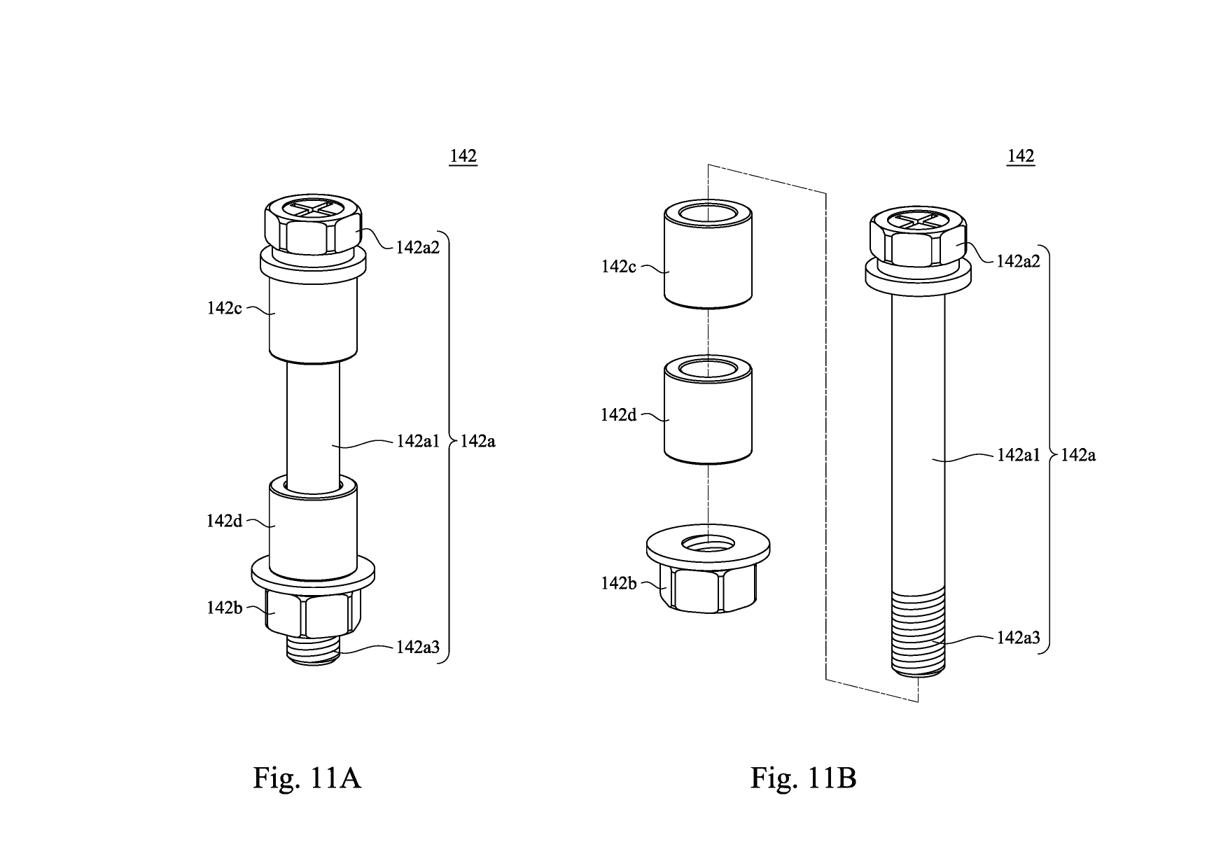

Reference is made to FIG. 11A and FIG. 11B. FIG. 11A is a schematic diagram illustrating the fixing assembly 142 in FIG. 10. FIG. 11B is an exploded view of the fixing assembly 142 in FIG. 11A. As shown in FIGS. 11A and 11B, the fixing assembly 142 includes a fastening member 142a, a nut 142b, and spacer posts 142c, 142d. The fastening member 142a includes a through portion 142a1, a head portion 142a2, and a fastening portion 142a3. The through portion 142a1 is connected between the head portion 142a2 and the fastening portion 142a3. The fastening member 142a can use the through portion 142a1 to pass through the spacer posts 142c, 142d. The nut 142b is detachably fastened to the fastening portion 142a3 of the fastening member 142a to retain the spacer posts 142c, 142d between the head portion 142a2 of the fastening member 142a and the nut 142b.

As shown in FIGS. 10 to 11B, the fastening member 142a can use the through portion 142a1 to pass through the bracket 112 and the two insulating extension arms 120. The head portion 142a2 of the fastening member 142a is located on a side of the upper insulating extension arm 120 away from the bracket 112. The nut 142b fastened to the fastening portion 142a3 is located on a side of the lower insulating extension arm 120 away from the bracket 112. Furthermore, the spacer post 142c passes through the upper insulating extension arm 120 and is abutted between the head portion 142a2 of the fastening member 142a and the bracket 112. The spacer post 142d passes through the lower insulating extension arm 120 and is abutted between the nut 142b and the bracket 112. It can be seen that by continuously fastening the nut 142b along the fastening portion 142a3 towards the head portion 142a2, the spacer post 142c, the bracket 112, and the spacer post 142d can be tightly clamped between the head portion 142a2 and the nut 142b.

In addition, by making the distance separated by the spacer post 142c between the head portion 142a2 and the bracket 112 greater than a thickness of the upper insulating extension arm 120, the upper insulating extension arm 120 can be movably retained between the head portion 142a2 and the bracket 112 along the spacer post 142c. In contrast, by making the distance separated by the spacer post 142d between the nut 142b and the bracket 112 greater than a thickness of the lower insulating extension arm 120, the lower insulating extension arm 120 can be movably retained between the nut 142b and the bracket 112 along the spacer post 142d. As a result, there is also a floating design between the bracket 112 and the two insulating extension arms 120, which is not only beneficial to eliminating the assembly tolerance between the electrical connector 321 and the conductive bar 130, but also prevents the bracket 112 from being deformed by the force applied by the insulating extension arms 120.

According to the foregoing recitations of the embodiments of the disclosure, it can be seen that in the power system of the present disclosure, the fixing member that fixes the conductive bar to the insulating extension arm allows the conductive bar to move toward and away from the insulating extension arm. Therefore, during the period when the power module of the disclosure is inserted into the cabinet of the power system and the conductive bar is inserted into the electrical connector of the power module, the floating design of the conductive bar relative to the insulating extension arm can effectively eliminate assembly tolerances between the electrical connector and the conductive bar. Since the conductive bar has the advantages of low cost, high reworkability, high current resistance, and high rated voltage, it can replace the conventional floating connector with specification limitations. By providing a guiding surface at the entrance of the connection port of the electrical connector and/or at the edge of the conductive bar inserted into the electrical connector, and with the floating mechanism of the conductive bar, the assembly tolerance can be maximized. By designing the housing of the power module with a notch for the insulating extension arm to pass through, and providing a guiding surface at the edge of the insulating extension arm and/or at the notch, the influence of the manufacturing tolerance of the power system on the assembly tolerance between the electrical connector and the conductive bar can be effectively eliminated. By providing a combination of a guiding pin and a guiding seat between the power module and the power system, the purpose of eliminating the aforementioned manufacturing tolerance on the assembly tolerance can also be achieved.

Although the present disclosure is disclosed in the above embodiments, the embodiments are not intended to limit the present disclosure. Anyone skilled in the art can make various changes and modifications without departing from the spirit and scope of the present disclosure. Therefore, the protection scope of the present disclosure shall be determined by the appended claims.

What is claimed is:

1. A power system, comprising:
a cabinet having an interior space and a bracket located in the interior space;
an insulating extension arm located in the interior space and fixed to the bracket;
a conductive bar located in the interior space;
a fixing member passing through the conductive bar and connected to the insulating extension arm, and allowing the conductive bar to move toward and away from the insulating extension arm; and
a power cord having an end electrically coupled to the conductive bar.

2. The power system of claim 1, wherein the insulating extension arm has a surface facing the conductive bar, and the fixing member comprises:
a through portion passing through the conductive bar and abutting against the surface of the insulating extension arm; and
a head portion connected to the through portion and located on a side of the conductive bar away from the insulating extension arm,
wherein the conductive bar is configured to be movable along the through portion between the surface of the insulating extension arm and the head portion.

3. The power system of claim 1, further comprising:
another insulating extension arm located in the interior space and fixed to the bracket;
another conductive bar located in the interior space;
another fixing member passing through the another conductive bar and fixed to the another insulating extension arm, and allowing the another conductive bar to move toward and away from the another insulating extension arm; and
an insulating member abutted between the insulating extension arm and the another insulating extension arm.

4. The power system of claim 3, wherein the fixing member passes through the insulating extension arm and is fastened to the insulating member, and the another fixing member passes through the another insulating extension arm and is fastened to the insulating member.

5. The power system of claim 1, wherein the insulating extension arm has a lateral extension portion, the lateral extension portion has an edge away from the bracket, and the edge has a guiding surface.

6. The power system of claim 1, wherein the conductive bar comprises a plugging portion, the plugging portion has an edge away from the bracket, and the edge has a guiding surface.

7. The power system of claim 1, further comprising another fixing member, wherein the another fixing member passes through the bracket and is fixed to the insulating extension arm, and allowing the bracket to move toward and away from the insulating extension arm.

8. The power system of claim 1, further comprising a guiding seat, wherein the guiding seat is connected to the insulating extension arm and has a guiding hole.

9. The power system of claim 1, further comprising a fixing assembly, the fixing assembly comprising:
a spacer post passing through the insulating extension arm; and
a fastening member comprising a through portion and a head portion connected to each other, wherein the through portion passes through the spacer post and passes into the bracket,
wherein the spacer post is abutted between the bracket and the head portion, and the insulating extension arm is movably retained between the bracket and the head portion.

10. The power system of claim 1, further comprising a fixing assembly, the fixing assembly comprising:
a spacer post passing through the insulating extension arm;
a fastening member comprising a through portion and a fastening portion connected to each other, wherein the through portion passes through the bracket; and
a nut detachably fastened to the fastening member,
wherein the spacer post is abutted between the bracket and the nut, and the insulating extension arm is movably retained between the bracket and the nut.

11. A power module configured to be inserted into the interior space of the power system of claim 1, the power module comprising:
a housing; and
a circuit board fixed in the housing and comprising an electrical connector, the electrical connector having a connection port, the connection port being configured for the conductive bar to plug into.

12. The power module of claim 11, wherein the housing comprises a sidewall, the sidewall has a notch, the notch is configured for the insulating extension arm of the power system to pass through, and the sidewall has a guiding surface configured to guide the insulating extension arm at the notch.

13. The power module of claim 11, wherein an entrance of the connection port has a guiding surface configured to guide the conductive bar.

14. The power module of claim 11, further comprising a guiding pin connected to the housing, wherein the power system further comprises a guiding seat, the guiding seat has a guiding hole, and the guiding pin is configured to slidably insert into the guiding hole.

15. A power system, comprising:
a cabinet having an interior space and a bracket located in the interior space, the interior space being configured for a power module to insert into;
an insulating extension arm located in the interior space and fixed to the bracket;
a conductive bar located in the interior space and configured to plug into a connection port of the power module;
a fixing member passing through the conductive bar and connected to the insulating extension arm, and allowing the conductive bar to move toward and away from the insulating extension arm; and
a power cord having an end electrically coupled to the conductive bar.
